(19) United States
(12) Patent Application Publication
(10) Pub. No.: US 2012/0307463 A1
(43) Pub. Date: Dec. 6, 2012

(54) DISPLAY DEVICE

(76) Inventors: Shuji YAMASHITA, Nara (JP); Takehiko Yamashita, Hyogo (JP)

(21) Appl. No.: 13/398,297

(22) Filed: Feb. 16, 2012

(30) Foreign Application Priority Data
May 31, 2011 (JP) 2011-121351

(51) Int. Cl. H05K 7/06

(52) U.S. Cl. 361/752

(57) ABSTRACT

The display device has a display module, a metal frame, and an exterior cabinet for accommodating the display module. The display module contains a display panel and a circuit board on which a driver circuit for displaying image on the panel is mounted. The metal frame is disposed in the periphery of the display panel. The exterior cabinet has a decorative panel and a back cover. The decorative panel is disposed on a front side of the display panel so as to cover the frame. The back cover covers a back side of the display module. The decorative panel is made of light transmissible colored resin. The decorative panel has an uneven thickness part, where a thickness changes continuously, at the section disposed on the frame.

### FIELD OF THE INVENTION

The present invention relates to a flat display device, such as a plasma display device using a low-profile, lightweight plasma display panel (hereinafter also referred to as a panel) as a display device.

### BACKGROUND OF THE INVENTION

The panels used for the plasma display devices roughly fall into two types of the alternating current (AC) type and the direct current (DC) type in the aspect of the principle of driving. On the other hand, from difference in discharging, the panels fall into the surface discharge type and the opposing discharge type. In recent years, the surface discharge device having a three-electrode structure has become the mainstream from the reasons of easy fabrication and suitability for increase in resolution and in screen size.

A panel of the surface discharge type has the following structure. Two substrates (where, each substrate has transparency at least on the front side) are oppositely disposed in a manner that a discharge space is formed therebetween. The discharge space is divided into a plurality of compartments by barrier ribs disposed on the substrates. The panel has an electrode array so as to generate a discharge in the discharge space divided by the barrier ribs. The panel has a plurality of discharge cells each of which containing phosphors that emit light of red, green, or blue. The phosphors are excited by vacuum-ultraviolet light with a short wavelength generated by a discharge, by which each discharge cell emits visible light of red, green, or blue. The panel thus provides color display.

Such structured plasma display panel has come under the spotlight particularly among the flat panel display devices. Compared to a liquid crystal panel, the plasma display panel has following advantages: fast-speed display; wide view angle; an easy development to increase in size; high display quality by virtue of self emission. With the structure above, the plasma display device has been widely used, for example, as a display device suitable for the area attracting large crowd or video entertainment for individuals at home.

For instance, Japanese Patent Unexamined Publication No. 2005-331556 introduces a module structure of a plasma display device. According to the structure, a panel mainly made of glass is fixed on the front side of a chassis member of aluminum or other metals. A circuit board including a driver circuit for panel emission is disposed on the back side of the chassis member.

The conventional structures, however, have a pending problem in providing a display device having a sophisticatedly designed exterior cabinet at low cost.

### SUMMARY OF THE INVENTION

The display device of the present invention has a display module, a metal frame, and an exterior cabinet. The display module contains a display panel and a circuit board on which a driver circuit for displaying image on the panel is mounted. The metal frame is disposed in the periphery of the display panel. The exterior cabinet accommodates the display module. The exterior cabinet has a decorative panel and a back cover. The decorative panel is disposed on a front side of the display panel so as to cover the frame. The back cover covers a back side of the display module. The decorative panel is made of light transmissible colored resin. The decorative panel has an uneven thickness part, where a thickness changes continuously, at a section disposed on the frame.

When light enters through the uneven thickness part of the decorative panel and reflects off the frame, the reflecting amount of light varies depending on the change in thickness of the uneven thickness part. The gradual change in light reflection produces a visual effect with stereoscopic gradation. Further, such a sophisticated design is obtained by a simple structure—the decorative panel with an uneven thickness part exhibiting continuous change in thickness is fixed to the metal frame disposed in the periphery of the panel. The simple structure contributes to a cost-reduced product.

### BRIEF DESCRIPTION OF THE DRAWINGS

FIG. 1 is a perspective view showing the structure of a plasma display device in accordance with an exemplary embodiment of the present invention.

FIG. 2 shows an electrode array diagram of the panel in accordance with the exemplary embodiment of the present invention.

FIG. 3 is a perspective view showing an appearance of the plasma display device in accordance with the exemplary embodiment of the present invention.

FIG. 4 is an exploded perspective view showing the entire structure of the plasma display device in accordance with the exemplary embodiment of the present invention.

FIG. 5 is a sectional view showing the structure of the main section of the plasma display device shown in FIG. 4.

FIG. 6 is an exploded perspective view showing another structure of the plasma display device in accordance with the exemplary embodiment of the present invention.

FIG. 7 is a sectional view showing the structure of the main section of the plasma display device shown in FIG. 6.

### DETAILED DESCRIPTION OF PREFERRED EMBODIMENT AN EXEMPLARY EMBODIMENT

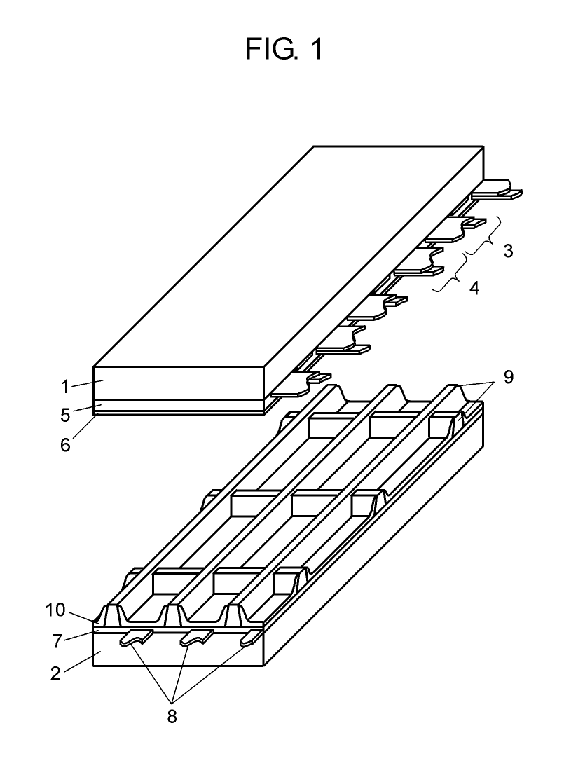

Hereinafter, a plasma display device as the display device of an exemplary embodiment of the present invention is described with reference to the accompanying drawings, FIG. 1 through FIG. 7. The exemplary embodiment is not to be construed as limitation of the present invention.

First, the structure of the plasma display panel (hereinafter simply referred to as a panel) of the plasma display device will be described with reference to FIG. 1. FIG. 1 is a perspective view showing the structure of the plasma display device in accordance with the exemplary embodiment of the present invention. The panel, as shown in FIG. 1, has front substrate 1 and rear substrate 2 made of glass. The two substrates are oppositely disposed to each other so as to form discharge space therebetween. On front substrate 1, display electrode pairs, each of which is formed of scan electrode 3 and sustain electrode 4, are arranged in parallel with each other. Dielectric layer 5 is formed to cover scan electrodes 3 and sustain electrodes 4, and over which, protective layer 6 is formed.

A plurality of data electrodes 8 is disposed on rear substrate 2 and insulation layer 7 covers data electrodes 8. On insulation layer 7, grid-like barrier ribs 9 are disposed. Phosphor layer 10 is formed on the surface of insulation layer 7 and on the side surfaces of barrier ribs 9. Front substrate 1 and rear substrate 2 are oppositely disposed to each other in a manner that the display electrode pairs (of scan electrodes 3 and sustain electrodes 4) are located orthogonal to data electrodes 8. The discharge space formed between the two substrates is filled with discharge gas, for example, a gas mixed neon with xenon. The panel does not necessarily have the structure above; barrier ribs 9 may be formed into stripes.

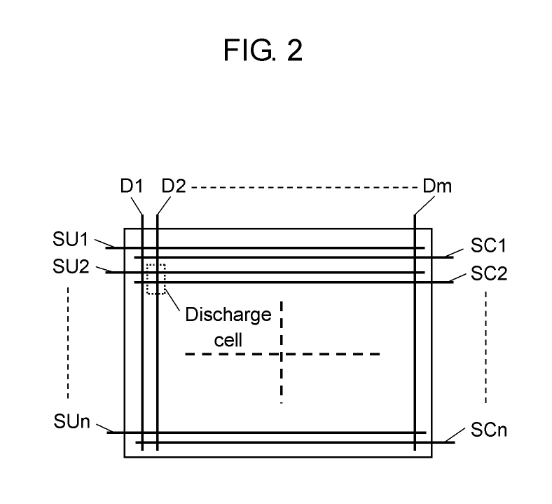

FIG. 2 shows an electrode array diagram of the panel on the exemplary embodiment. The panel has n scan electrodes SC1 through SCn (corresponding to scan electrodes 3 of FIG. 1) and n sustain electrodes SU1 through SUn (corresponding to sustain electrodes 4 of FIG. 1) in the row direction, and has m data electrodes D1 through Dm (corresponding to data electrodes 8 of FIG. 1) in the column direction. A discharge cell is formed at the part where a pair of scan electrode SCi (i=1 to n) and sustain electrode SUi intersects one data electrode Dj (j=1 to m). That is, m×n discharge cells are formed in the discharge space.

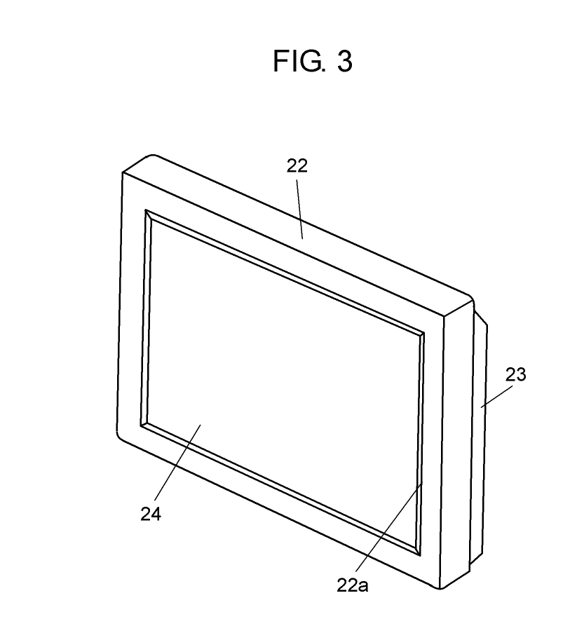

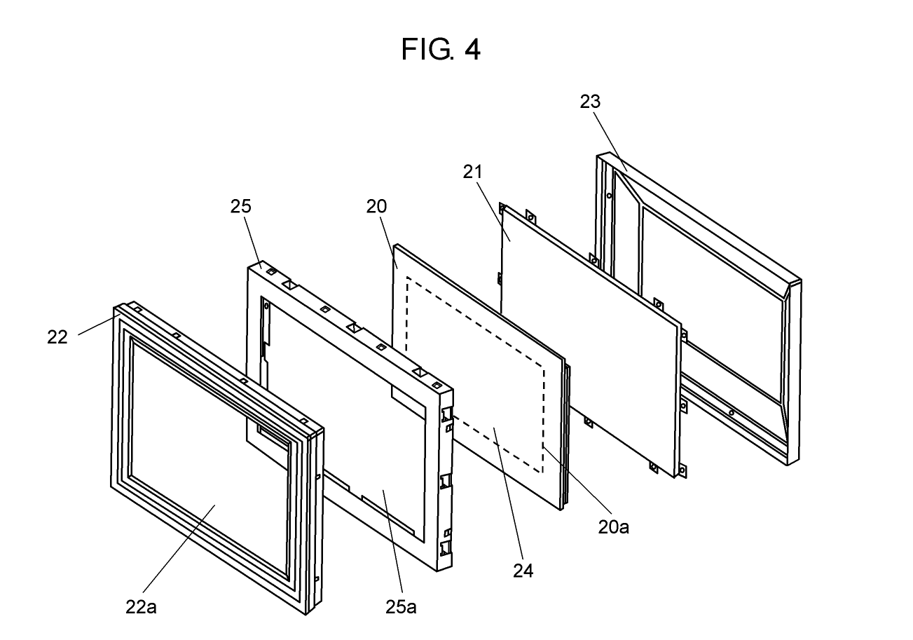

FIG. 3 shows an appearance of the plasma display device (including the panel with the aforementioned structure) of the exemplary embodiment. FIG. 4 shows the entire structure of the plasma display device (including the panel with the aforementioned structure) of the exemplary embodiment. The aforementioned panel is shown as display panel 20 in FIG. 4 or later so as to be distinguished from decorative panel 22.

As shown in FIGS. 3 and 4, display panel 20 is disposed on a front side of holding plate 21 made of metal, for example, aluminum. A circuit board (not shown) having a driver circuit for displaying image on display panel 20 is disposed on a back side of holding plate 21. Display panel 20, holding plate 21, and the circuit board having the driver circuit thereon form a display module. The display module is accommodated in the exterior cabinet. The exterior cabinet has decorative panel 22 on a front side, and has metal back cover 23 that covers a back side of the display module. Decorative panel 22 is made of light transmissible colored resin material.

On the front side of display panel 20, an optical filter containing electromagnetic shielding filter 24 is disposed. Electromagnetic shielding filter 24 is electrically connected to holding plate 21 via metal frame 25 disposed in the periphery of display panel 20. Frame 25 has opening 25a that conforms to display area 20a of display panel 20. Frame 25 is made of a metal with high brightness, such as aluminum and stainless-steel, and is disposed on display panel 20 so as to cover the non-display area surrounding the display area.

Decorative panel 22 of the exterior cabinet has opening 22a that conforms to display area 20a of display panel 20. Decorative panel 22 is disposed over frame 25 so as to have contact with each other.

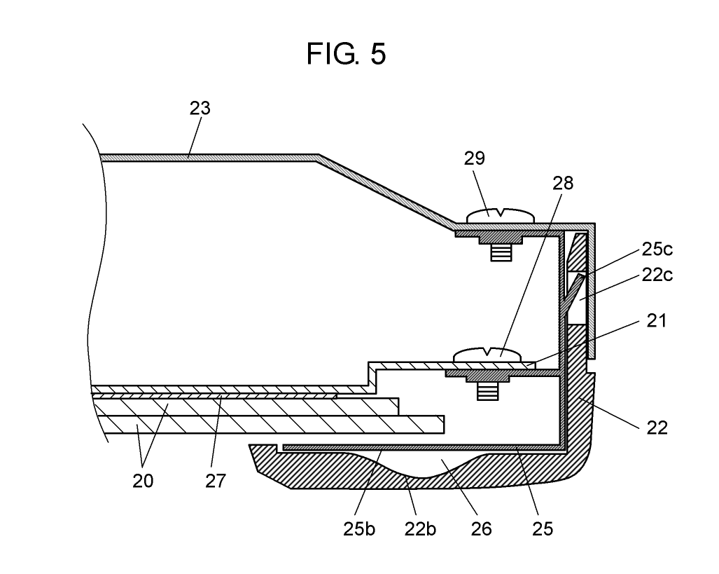

FIG. 5 is a sectional view showing the structure of the main section of the plasma display device shown in FIG. 4.

Decorative panel 22, as shown in FIG. 5, has uneven thickness part 22b on the front side. Uneven thickness part 22b having continuous change in thickness is formed in a section disposed on frame 25. Therefore, space 26 is formed between decorative panel 22 and frame 25 at uneven thickness part 22b. Besides, frame 25 has mirror-finished surface 25b that faces uneven thickness part 22b of decorative panel 22. With the structure above, when light enters through uneven thickness part 22b of decorative panel 22 and reflects off surface 25b of frame 25, the reflecting amount of light varies depending on the change in thickness of uneven thickness part 22b. The aforementioned structure offers an excellent design having visual effect with stereoscopic gradation.

Display panel 20 is fixed on the front surface of holding plate 21 via sheet 27 having elasticity and thermal conductivity. Further, holding plate 21 is electrically and mechanically connected to metal frame 25 by screw 28. Similarly, back cover 23 of metal is electrically and mechanically connected to metal frame 25 by screw 29.

Metal frame 25 has incised tab 25c on the side surface, whereas decorative panel 22 has hole 22c that meets with tab 25c. Decorative panel 22 is disposed over frame 25 in a manner that incised tab 25c of frame 25 is fitted in hole 22c of decorative panel 22. Thus, decorative panel 22 is tightly attached to frame 25. That is, frame 25 is disposed over decorative panel 22 so as to have contact with each other. Back cover 23 covers the side surface of decorative panel 22 disposed over frame 25.

Hereinafter, the exterior cabinet with a design producing a stereoscopic gradation effect will be described.

Decorative panel 22, as described above, is made of a light transmissible colored resin. Further, decorative panel 22 has uneven thickness part 22b on the front side. Uneven thickness part 22b having continuous change in thickness is formed in a section disposed on frame 25. The front surface of frame 25 has mirror-finished surface 25b at a part that faces uneven thickness part 22b. When light enters into the surface of decorative panel 22, it travels through uneven thickness part 22b and reflects off surface 25b of frame 25, and then comes back through uneven thickness part 22b. At this time, the reflection amount of the coming-back light varies depending on the change in thickness of uneven thickness part 22b. The gradual change in light reflection provides the design of the cabinet with a stereoscopic gradation effect. Adjusting the color density of the colored resin material of decorative panel 22 allows the design to have variations. For example, a resin material of pale color enhances the hard and shiny feel of metal frame 25, whereas a resin material of dark color produces a soft and low-keyed image.

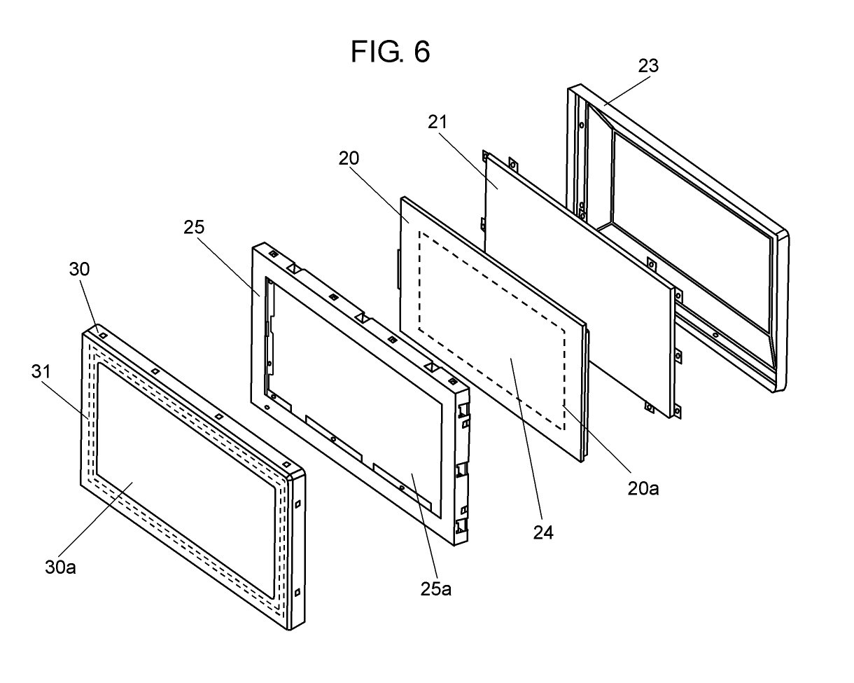

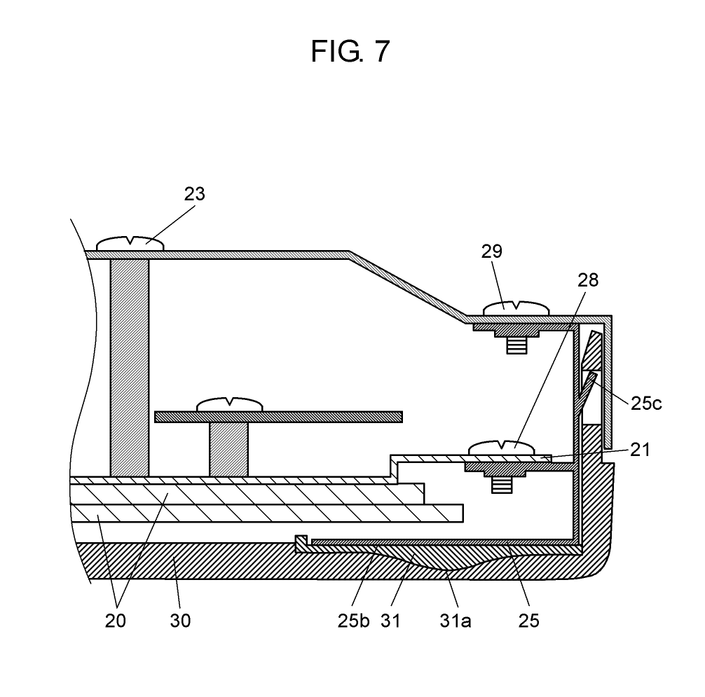

Next, another structure of the plasma display device of the embodiment will be described with reference to FIGS. 6 and 7. FIG. 6 is an exploded perspective view showing another structure of the plasma display device of the embodiment. FIG. 7 is a sectional view showing the structure of the main section of the plasma display device shown in FIG. 6.

In FIGS. 6 and 7, front panel 30 and back cover 23 form an exterior cabinet. Front panel 30 has a shape of a flat plate without opening and covers frame 25. Front plate 30 has transparent display window 30a for display area 20a of display panel 20.

As described earlier, the exterior cabinet accommodates the display module. The display module has display panel 20 on the front side of metallic holding plate 21 and the circuit board (not shown) on the back side of holding plate 21. The circuit board contains the driver circuit for displaying image on display panel 20.

On the front side of display panel 20, an optical filter containing electromagnetic shielding filter 24 is disposed. Electromagnetic shielding filter 24 is electrically connected to holding plate 21 via metal frame 25 disposed in the periphery of display panel 20. Frame 25 has opening 25a that conforms to display area 20a of display panel 20. Frame 25 is made of a metal with high brightness, such as aluminum and stainless-steel, and is disposed on display panel 20 so as to cover the non-display area surrounding the display area.

In the periphery section of front panel 30 (i.e., the section disposed over frame 25 so as to cover the non-display area of display panel 20), decorative panel 31 is embedded. Decorative panel 31 is made of a transparent colored resin material. Decorative panel 31 has uneven thickness part 31a on the front side. Decorative panel 31 has uneven thickness part 31a, where a thickness changes continuously, at a section disposed on frame 25. Decorative panel 31 is laid over frame 25 so as to have contact with each other. Besides, frame 25 has mirror-finished surface 25b that faces uneven thickness part 31a of decorative panel 31. With the structure above, when light enters through uneven thickness part 31a of decorative panel 31 and reflects off surface 25b of frame 25, the reflecting amount of light varies depending on the change in thickness of uneven thickness part 31a. The aforementioned structure offers an excellent design having visual effect with stereoscopic gradation.

As described above, the display device of the embodiment has the display module, metal frame 25, and the exterior cabinet for accommodating the display module. The display module contains display panel 20 and the circuit board on which the driver circuit for displaying image on display panel 20 is mounted. The exterior cabinet contains decorative panel 22, 31 on the front side so as to cover frame 25, and back cover 23 that covers the back side of the display module. Decorative panel 22, 31 is made of a light transmissible colored resin. Decorative panel 22, 31 has uneven thickness part 22b, 31a on the front side. Decorative panel 22, 31 has uneven thickness part 22b, 31a, where a thickness changes continuously, at a section disposed on frame 25. When light enters into the surface of decorative panel 22, 31, it travels through uneven thickness part 22b, 31a and reflects off surface 25b of frame 25, and then comes back through uneven thickness part 22b, 31a. At this time, the reflection amount of the coming-back light varies depending on the change in thickness of uneven thickness part 22b, 31a. The gradual change in light reflection provides the design of the cabinet with a stereoscopic gradation effect. Adjusting the color density of the colored resin material of decorative panel 22, 31 allows the design to have variations. For example, a resin material of pale color enhances the hard and shiny feel of metal frame 25, whereas a resin material of dark color produces a soft and low-keyed image.

Although frame 25 is made of aluminum or stainless-steel and has the mirror-finished front surface in the structure of the embodiment, it is not limited to. Frame 25 may be made of a steel plate whose surface is painted or printed by an ink having specularity, or made of a steel plate laminated with a mirror-finished sheet.

What is claimed is:

1. A display device comprising:
a display module including:
a display panel; and
a circuit board on which a driver circuit for displaying image on the display panel is mounted;
a metallic frame disposed in the periphery of the display panel; and
an exterior cabinet for accommodating the display module, the exterior cabinet including:
a decorative panel disposed on a front side of the display panel so as to cover the frame; and
a back cover for covering a back side of the display module,
wherein the decorative panel is made of light transmissible colored resin material, and the decorative panel has an uneven thickness part, where a thickness changes continuously, at a section disposed on the frame.

2. The display device according to claim 1,
wherein the frame has a mirror-finished surface at a section facing the uneven thickness part of the decorative panel.

3. The display device according to claim 1,
wherein the decorative panel is laid over the frame so as to have contact with each other.

4. A display device comprising:
a display module including:
a display panel;
a metallic holding plate for holding the display panel on front side; and
a circuit board on which a driver circuit for displaying image on the panel is mounted, the circuit board disposed on a back side of the holding plate;
an electromagnetic shielding filter disposed on a front side of the display panel;
a metallic frame disposed in a periphery of the display panel so as to electrically connect the electromagnetic shielding filter to the holding plate; and
an exterior cabinet for accommodating the display module, the exterior cabinet including:
a decorative panel disposed on a front side of the display panel so as to cover the frame; and
a back cover for covering the back side of the display module,
wherein the decorative panel is made of light transmissible colored resin material, and the decorative panel has an uneven thickness part, where a thickness changes continuously, at a section disposed on the frame.

5. The display device according to claim 4,
wherein the frame has a mirror-finished surface at a section facing the uneven thickness part of the decorative panel.

6. The display device according to claim 4,
wherein the decorative panel is laid over the frame so as to have contact with each other.
